(19) United States
(12) Patent Application Publication
(10) Pub. No.: US 2007/0263373 A1
(43) Pub. Date: Nov. 15, 2007

(54) Packaged electronic component for shielding electromagnetic interference

(75) Inventors: Chih-Tse Chen, Taoyuan Hsien (TW); Ching-Man Kao, Taoyuan Hsien (TW); Han-Cheng Hsu, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/790,630

(22) Filed: Apr. 26, 2007

(30) Foreign Application Priority Data
May 11, 2006 (TW) 95116705

(51) Int. Cl. H05K 9/00

(52) U.S. Cl. 361/818

(57) ABSTRACT

A packaged electronic component capable of shielding electromagnetic interference (EMI) includes a case, at least one magnetic component, a circuit board, and an anti-noise clip. The magnetic component is electrically connected to the circuit board and is covered by the case. Further, the anti-noise clip is mounted on and is clipped to the exterior of the case and is electrically connected with the circuit board to form a grounded loop.

The present application claims priority under U.S.C.§ 119(a) on Patent Application No(s). 095116705, filed in Taiwan, Republic of China on May 11, 2006, the entire contents of which are hereby incorporated by reference.

### BACKGROUND OF THE INVENTION

1. Field of the Invention

The invention relates to a packaged electronic component, and in particular to a packaged electronic component capable of shielding electromagnetic interference (EMI).

2. Description of the Related Art

Referring to FIG. 1, a conventional packaged electronic component 1 is constituted by a plurality of pins 12 and a molding case 11 which is made by plastic. The molding case 11 accommodates at least one coil (not shown), and the pins 12 are disposed at two both sides of the case 11.

Due to the increased number of functions performed by current IC chips, amount of electromagnetic wave activity is increased. When several electronic components are arranged together, the IC chips or other components producing noise affect the operation of nearby electronic components. Hence, electromagnetic waves produced by other components adversely affect the conventional packaged electronic component 1, resulting in poor performance thereof. Thus, a packaged electronic component capable of shielding electromagnetic interference (EMI) is desirable.

### BRIEF SUMMARY OF THE INVENTION

The invention provides a packaged electronic component capable of shielding electromagnetic interference (EMI).

The packaged electronic component includes a case, at least one magnetic component, a circuit board and an anti-noise clip. The case is formed by a molding material and the case covers the magnetic component and the circuit board. The magnetic component is electrically connected with the circuit board. The anti-noise clip mounts on and surrounds the package case and is electrically connected with a ground portion of the circuit board so as to form a grounded loop.

Additionally, the magnetic component can be a coil with silica gel wrapped around the surface thereof. The anti-noise clip is made of a metal material and is connected with the ground portion of the circuit board via a pad on the circuit board.

The packaged electronic component further includes a plurality of pins, disposed at two sides of the case. The packaged electronic component is preferably a surface mounted device.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is 3-D view of a conventional packaged electronic component;

FIG. 2 is a 3-D view of an embodiment of a packaged electronic component in accordance with the present invention;

FIG. 3 is a side view of FIG. 2, showing the side on which the pins extend; and

FIG. 4 is a sectional view of FIG. 2.

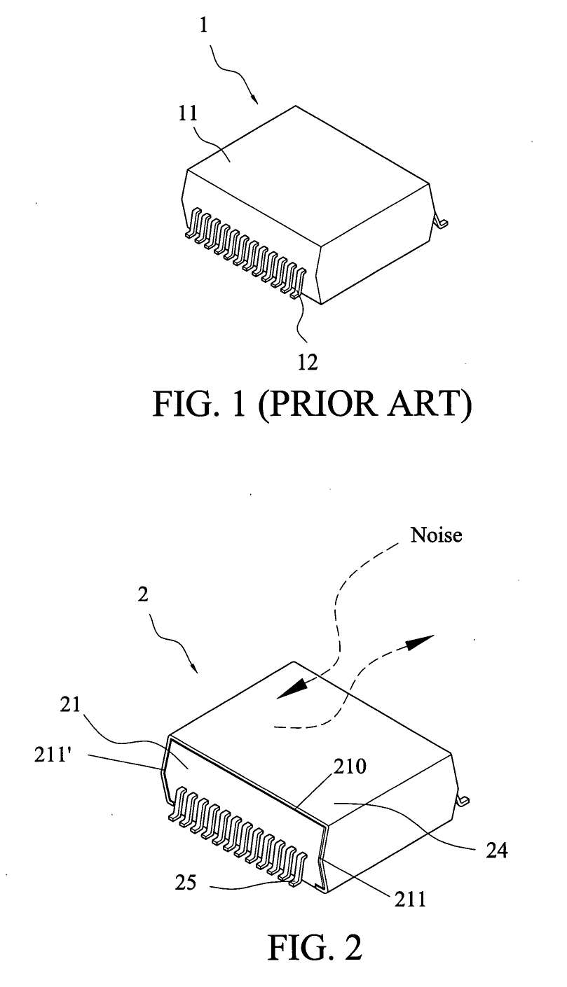

### DETAILED DESCRIPTION OF THE INVENTION

A packaged electronic component capable of shielding EMI is described with reference to the attached drawings, wherein the same components share the same reference numerals.

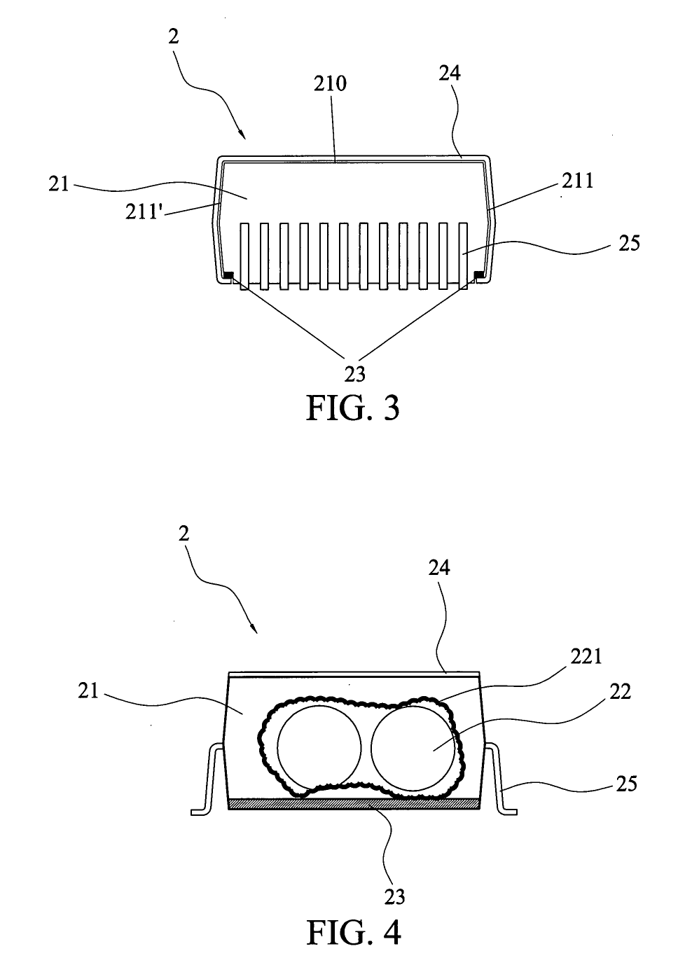

Referring to FIG. 2, FIG. 3, and FIG. 4, the packaged electronic component 2 of an embodiment of the present invention includes a case 21, at least one magnetic component 22, a circuit board 23, and an anti-noise clip 24 mounting on the case 21.

The case 21 is made of a molding material, such as epoxy resins. The case 21 covers and accommodates the magnetic component 22 and the circuit board 23. In this embodiment, the magnetic component 23 is a coil. Preferably, the exterior of the magnetic component 22 is wrapped by a silica gel 221 for protection and insulation of the magnetic component 22. Moreover, there are a plurality of pins 25 disposed two opposite side surfaces of the case 21 for electrically connecting with other equipments or components. The pins 25 do not contact the anti-noise clip 24. Preferably, the packaged electronic component 2 is a surface mounted device (SMD).

The case 21 is clipped tightly by the anti-noise clip 24. In this embodiment, the anti-noise clip 24 tightly mounts on the top surface 210 and the side surfaces 211 and 211′ of the case 21, and is electrically connected with the ground portion of the circuit board 23 to form a grounded loop. Preferably, the circuit board 23 has at least a pad electrically connected to the ground portion. The pad contacts the anti-noise clip 24 to form an electrical connection therebetween. The anti-noise clip 24 is preferably made of a metal material, such as copper, to achieve a better shielding effect.

In this embodiment, the case 21 covering and electrically connecting the anti-noise clip 24 with the ground portion of the circuit board 23 provides EMI resistance.

Thus, the present invention provides a packaged electronic component with an anti-noise clip tightly holding the case and electrically connecting with the ground portion of the circuit board to form a grounding loop, for shielding the packaged electronic component, preventing from electromagnetic interference and keeping operation normal. Compared with the conventional packaged electronic component, the present invention is more suitable for the electronic component with high density and high noise.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A packaged electronic component, comprising:
at least one magnetic element;
a circuit board electrically connected to the magnetic element;
a case covering the at least one magnetic element and the circuit board; and
an anti-noise clip mounting on the case and being electrically connected to the circuit board to form a grounded loop.

2. The packaged electronic component as claimed in claim 1, wherein the anti-noise clip covers a top surface and all side surfaces of the case.

3. The packaged electronic component as claimed in claim 1, further comprising a silica gel, wherein the magnetic component is wrapped by the silica gel.

4. The packaged electronic component as claimed in claim 1, wherein the anti-noise clip comprises metal materials.

5. The packaged electronic component as claimed in claim 4, wherein the anti-noise clip comprises copper.

6. The packaged electronic component as claimed in claim 1, wherein the case is composed of a molding material.

7. The packaged electronic component as claimed in claim 6, wherein the molding material comprises epoxy resins.

8. The packaged electronic component as claimed in claim 1, wherein the magnetic component is a coil.

9. The packaged electronic component as claimed in claim 1, further comprising a plurality of pins, disposed at two opposite sides of the case.

10. The packaged electronic component as claimed in claim 9, wherein the packaged electronic component is a surface mounted device.

11. The packaged electronic component as claimed in claim 1, wherein the circuit board comprises a ground portion, and the anti-noise clip is electrically connected with the ground portion of the circuit board.

12. The packaged electronic component as claimed in claim 11, wherein the anti-noise clip is electrically connected with the ground portion via a pad on the circuit board.
